(19) United States
(12) Patent Application Publication
(10) Pub. No.: US 2004/0055539 A1
(43) Pub. Date: Mar. 25, 2004

(54) Reactive-reactor for generation of gaseous intermediates

(75) Inventors: Chung J. Lee, Fremont, CA (US); Atul Kumar, Fremont, CA (US); Oanh Nguyen, Union City, CA (US); Jeff Wu, Palo Alto, CA (US); Chieh Chen, Palo Alto, CA (US)

Correspondence Address: JACKSON WALKER LLP, 2435 NORTH CENTRAL EXPRESSWAY, SUITE 600, RICHARDSON, TX, 75080, US

(73) Assignee: DIELECTRIC SYSTEMS, INC., Fremont, CA (US)

(21) Appl. No.: 10/243,990

(22) Filed: Sep. 13, 2002

(51) Int. Cl. C23C 16/00; H01F 41/00

(52) U.S. Cl. 118/724; 427/457; 427/508

(57) ABSTRACT

A semiconductor equipment that is useful for the fabrication of integrated circuits (“IC”). More specifically, this invention relates to a “reactive-reactor” for a transport polymerization (“TP”) process module, wherein the process module is useful for the deposition of low dielectric (“ε”) thin films in IC manufacture. The reactive-reactor has reactive metal interior surfaces for effective conversion of precursors to intermediates. The resultant reaction products of the precursor and the interior surface material of the reactive-reactor are very stable, and do not cause metallic contamination of the semiconductors. The reactive-reactor of this invention is also equipped with Reactor Re-generating capacity to restore the reactive metal interior surfaces.

### BACKGROUND

This invention is related to semiconductor equipment that is useful for the fabrication of integrated circuits (“IC”). More specifically, this invention is related to a “Reactive” reactor for the generation of intermediates that are useful for the deposition of low dielectric (“ε”) thin films in IC manufacture. The reactive-reactor has a very high surface-to-volume ratio, which makes it very compact, and it has reactive interior surfaces for effective conversion of precursors to intermediates. The intermediates are transported to a deposition chamber and polymerized onto wafer. The deposition system is thus called a Transport Polymerization (“TP”) System. The reactive-reactor is also equipped with an Reactor Re-generating Subsystem, which makes the reactive-reactor suitable for use in the process module system disclosed in the co-pending patent application, entitled “Process Modules for Transport Polymerization of Low ε thin films,” with Ser. No. 10/125,626. This co-pending application was filed on Apr. 19, 2002, with Lee, et al. listed as inventors, and the entirety of which is hereby incorporated by reference.

As a consequence of shrinking IC device geometries, interconnects have exhibited an increase in capacitance, which can result in unacceptable cross talk and resistance-capacitance (“RC”) delay. This RC delay has become a serious problem for ICs with feature size of less than 0.18 μm. Thus, the dielectric constant of the current insulation materials from which IC's are constructed must be decreased to meet the needs for fabrication of future ICs. In addition to dielectric and conducting layers, the “barrier layer” may include metals such as Ti, Ta, W, and Co and their nitrides and suicides, such as TiN, TaN, TaSixNy, TiSixNy, WNx, CoNx and CoSiNx. Ta is currently the most useful barrier layer material for the fabrication of IC's that currently use copper as conductor. The “cap-layer” or “etch-stop-layer” normally consists of dielectric materials such as SiC, SiN, SiON, SiyOx and its fluorinated silicon oxide (“FSG”), SiCOH, and SiCH. Thus, the new dielectric materials must also withstand many other manufacturing processes following their deposition onto a substrate.

Currently, there are two groups of low ε dielectric materials, which include a traditional inorganic group, exemplified by SiO₂, its fluorine doped product, FSG and its C & H doped products, SiOₓC_{y}H_{z} and newer organic polymers, exemplified by SiLK, from Dow Chemical Company. Chemical Vapor Deposition (“CVD”) and spin-on coating method have been used to deposit the inorganic and polymer dielectric films respectively. These current dielectric materials used in the manufacturing of the ICs have already proven to be inadequate in several ways for their continued use in mass production of the future IC's. For example, these materials have high dielectric constants (ε≧2.7), they have low yield (<5-7%) and marginal rigidity (Young's Modulus less than 4 GPa). In light of the shortcomings of current dielectric materials, a director of a major dielectric supplier has suggested that the use of thin films with high dielectric constants (e.g. ε=3.5) will be extended to the current 130 nm devices (A. E. Brun, “100 nm: The Undiscovered Country”, Semiconductor International, February 2000, p79). This statement suggests that the current dielectric thin films are at least four years behind the Semiconductor Industrial Association's (“SIA”) road map. The present lack of qualified low dielectric materials now threatens to derail the continued shrinkage of future IC's.

Currently, all conventional CVD processes have failed to make useful ε<2.7, Ta-compatible thin films. Due to many unique advantages that will be revealed in the following sections, we believe that TP soon will emerge as a primary CVD approach for fabrications of future IC's. Some of the important chemistries and mechanisms involved during TP has been reviewed previously (Chung Lee, “Transport Polymerization of Gaseous Intermediates and Polymer Crystals Growth” J. Macromol. Sci-Rev. Macromol. Chem., C16 (1), 79-127 (1977-78), pp79-127, and is hereby incorporated by reference).

TP vs. CVD Processes: There are several fundamental differences between the Transport Polymerization (“TP”) and conventional CVD processes. First, in all traditional CVD processes, starting chemicals are introduced into a CVD chamber where the “feed chemicals” are subjected to needed energy sources such as plasma or ozone to generate reacting intermediates. Film will grow when these intermediates impinge onto a substrate, such as a wafer. Second, in these CVD processes, a wafer is normally heated and a CVD chamber is normally operated under sub-atmosphere pressure or moderate vacuum in the ranges of a few mTorrs to few Torrs. Third, in these CVD processes, film not only grows on wafer but also on chamber wall. Fourth, conventional CVD processes using ozone oxidative processes are not suitable for making organic thin films. Fifth, current CVD dielectrics that are prepared from plasma polymerization of Organo-Siloxanes have ε of about 2.7 or higher.

Plasma polymerization of organic precursors can provide ε of lower than 2.7, however, they inherit many drawbacks, which include:

1. Due to poorly selective cracking of chemical bonds by plasma, some feed chemicals can end up with several reactive sites but others still have none during plasma polymerization. To avoid this disparity by increasing power levels for instance, films with highly cross-linked density and high residual stress would result.

2. During plasma polymerization, free radicals, anions, and ions with various reactive sites on each intermediate will be generated. Since intermediates with different molecular orbital configurations likely will not react with each other, some of these intermediates will have no chance to react and become a part of the resulting network. Due to this inherent complexity, plasma polymerization commonly results in poor yield (few percent) and films with different chemical structures at molecular levels.

3. Since all kinds of reactive intermediates, including very corrosive fluorine ion or radical could be generated, it is also desirable to heat the substrate, so condensation of low molecular weight products, corrosive species and not reacted impurities can be avoided. However, with presence of corrosive species such as fluorine ion, corrosion of underlying metal such as a barrier metal on wafer can become a serious problem when wafer is kept at high temperatures.

4. In addition, when more than 15 to 20 molar % of multi-functional intermediates consisting of more than two reactive sites are present inside chamber, most of these reactive sites will be trapped inside the polymer networks or become chain ends. Post annealing is done under controlled reductive or hydrogen atmosphere before the film is removed from vacuum chamber. This is needed to eliminate these reactive chain ends in order to avoid later reactions of these reactive chain ends with undesirable chemicals such as water or oxygen.

5. Finally, presence of many polymer chain-ends and pending short chains in polymer networks will result in high dielectric loss, thus the resulting dielectric will not be useful for high frequency (GHz) applications that are critical to most future IC applications.

For the reasons listed above, all conventional CVD processes have failed to make useful ε<2.7, Ta-compatible thin films.

The State of Transport Polymerization: Transport polymerization (“TP”) employs known chemical processes to generate desirable reactive intermediates among other chemical species. Chemical processes that are particularly useful for this invention include photolysis and thermolysis. These two chemical processes can generate useful reactive intermediates such as carbenes, benzynes and other types of diradicals using appropriate precursors.

Photolysis can be accomplished by irradiation of compounds using electrons, UV or X-ray. However, high energetic electron and X-ray sources are expensive and typically not practical for reactors useful for this invention. When a UV photolytic process is used, a precursor that bears special leaving groups is normally required. For example, reactive intermediates such as carbenes and diradicals can be generated by the UV photolysis of precursors that bear ketene or diazo groups. However, these types of precursors normally are expensive and not practical to use due to their very unstable nature at ambient temperatures. Other precursors and chemistry have been used for generating reactive intermediates and discussed in prior art (C. J. Lee, “Transport Polymerization of Gaseous Intermediates and Polymer Crystals Growth” J. Macromol. Sci-Rev. Macromol. Chem., C16 (1), 79-127 (1977-78), pp79-127). However, most of these precursors are quite expensive to prepare and are not readily available, thus they are not desirable nor practical for IC fabrications outlined in the current invention. In the co-pending application with U.S. Ser. No. 10/115,879, entitled “UV Reactor for Transport Polymerization,” a specially designed UV Reactor is used for Transport Polymerization and thin film preparation of some thermally stable precursors. This co-pending application was filed on Apr. 4, 2002, with Lee, et al. listed as inventors and is hereby incorporated by reference.

Thermolysis has been used for TP of poly (Para-Xylylenes) (“PPX”) for the coating of circuit boards and other electronic components since early 1970s. Currently, all commercial PPX films are prepared by the Gorham method (Gorham et al., U.S. Pat. No. 3,342,754, the content of which is hereby incorporated by reference). The Gorham method employed dimer precursor (I) that cracks under high temperatures (e.g. 600 to 680° C.) to generate a reactive and gaseous diradical (II) under vacuum. When adsorbed onto cold solid surfaces, the diradical (II) polymerizes to form a polymer film (III).

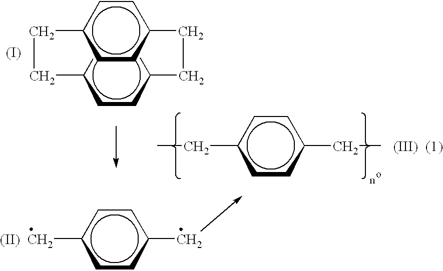

Since 1970, several commercialized products have appeared on the market with similar chemical structures. For example, a polymer PPX-D (—CH₂—C₆H₂Cl₂—CH₂—) had a dielectric constants, ε of 3.2. However, all these polymers were not thermally stable at temperatures higher than 300 to 350° C., and were not useful for fabrications of future ICs that require dielectric with lower ε and better thermal stability. On the other hand, the PPX-F,-(CF₂—C₆H₄—CF₂—)N has a ε=2.23 and is thermally stable up to 450° C. over 2.5 hours in vacuum. Therefore, rigorous attempts have been made to make PPX-F from dimer (—CF₂—C₆H₄—CF₂—)₂ (Wary et al, Proceedings, 2nd Intl. DUMIC, 1996 pp207-213; ibid, Semiconductor Int'l, 19(6), 1996, p211-216) using commercially available equipment. However, these efforts were abandoned due to high cost of the dimer and incompatibility of the barrier metal (e.g. Ta) with PPX-F films prepared by TP (Lu et al, J. Mater. Res. Vol,14(1), p246-250, 1999; Plano et al, MRS Symp. Proc. Vol. 476, p213-218, 1998—these cited articles are herby incorporated by reference.)

Many commercial deposition systems have been available for deposition of PPX since early 1970. These deposition systems comprise primarily the same four main components, as shown in the prior art 100 in FIG. 1: a sample holder and material delivery system 105 is in fluid communication with the reactor 120 through a needle valve 110. The deposition chamber 130 is in fluid communication with the reactor 120 and the cold trap 140. Additionally, the entire system is connected to a vacuum system.

In these reactors, a resistive heater and a stainless steel reactor (i.e. pyrolyzer) are used to crack dimers. Additionally, a tubular quartz reactor has been used to crack the dimer (e.g. (—CH₂—C₆H₄—CH₂—)₂ as shown above in equation (I)), and used for making PPX-N (Wunderlich and associates (Wunderlich et al, Jour. Polymer. Sci. Polymer. Phys. Ed., Vol. 11, (1973), pp 2403-2411; ibid, Vol. 13, (1975), ppl925-1938). It is important to note that the PPX-N dimer (e.g. (—CH₂—C₆H₄—CH₂—)₂) bears no halogen, and thus there was no potential corrosion of the stainless steel reactor during preparation of PPX-N. In other words, a stainless steel pyrolyzer can only be used for a dimer that has halogens on a Sp²C carbon to make PPX-D (—CH₂—C₆H₂Cl₂—CH₂—), but it is not compatible with a precursor consisting of halogens on the Sp³C, for example, a precursor such as formula (IV) of the following:

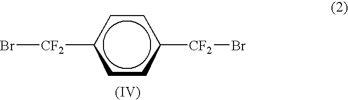

When (IV) is used, the iron inside the pyrolyzer's surfaces can react with the bromine if the temperature inside the pyrolyzer is higher than 420 to 450° C. However, the metallic impurities in the Stainless Steel contaminate the dielectric film and make it unsuitable for IC fabrications. Other shortcomings of commercial PM's are that they are not equipped with a proper deposition chamber for wafer or a vapor controller, which is important to the current invention. Thus, these commercial process modules are not useful for the present invention that uses halogen-containing precursors.

U.S. Pat. No. 5,268,202 with Moore listed as inventor (“the Moore '202 patent”), teaches that a dibromo-monomer (e.g. IV=(Br—CF₂—C₆Cl₄—CF₂—Br)) and a metallic “catalyst” (Cu or Zn) or metal-reactant inside a stainless steel pyrolyzer can be used to generate reactive free radical (V) according to the reaction (3). However, to lower the cost of starting materials, a large proportion (>85 to 95 molar %) of a more readily available co-monomer with structure (CF₃—C₆H₄—CF₃) has also been used to make PPX-F.

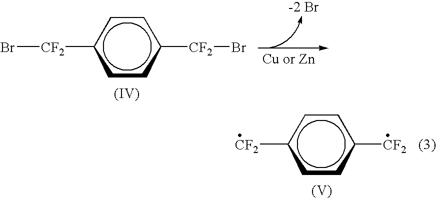

There are several key points that need to be addressed concerning the usage of the monomer (IV) in reaction (3). First, an earlier U.S. Pat. No. 3,268,599 (“the Chow '599 patent”) with Chow listed as inventor, revealed the chemistry to prepare a dimmer as early as 1966. However, the Chow '599 patent only taught the method to prepared dimer (CF₂—C₆H₄—CF₂)₂ by trapping the diradical (V) in a solvent. Furthermore, the equipment and processing methods of the Chow '599 patent employed were not suitable for making thin films that are useful for IC fabrications. Second, according to the Moore '202 patent, the above reaction (3) would need a cracking temperature ranging from 660-680° C., without using the “metal-reactants”.

However, we found that metallic “reactants” such as Zn or Cu would readily react with organic bromine at temperatures ranging from 300 to 450° C., the pyrolyzer temperatures employed by the Moore '202 patent. Formation of metallic halides on surfaces of these “reactants” would quickly deactivate these “reactants” and inhibit further de-bromination shown in reaction (3). In addition, the presence of Zn and Cu halides inside a pyrolyzer would likely cause contamination for the process module and dielectric films on wafer. Third, cooling of reactive intermediate and wafer cooling is efficient because both the wafer holder and pyrolyzer were located inside a close system for the deposition chamber that was used in the Moore '202 patent. Consequently, the process module used by the Moore '202 patent cannot be useful for preparation of thin films of this invention.

In this invention, a reactive-reactor is constructed using reactive or catalytic interior surface material that will not cause contamination is described. Thus, the reactive-reactor can be used to generate gaseous intermediates for manufacturing of low k dielectric films that are free from metallic contamination. The reactive-reactor also comprises a Reactor Re-generating Sub-system (“RRS”) to ensure the deposition system meets the requirements for wafer throughput, and is suitable for manufacturing of ICs.

### SUMMARY

This invention is related to semiconductor equipment that is useful for the fabrication of integrated circuits (“IC”). More specifically, this invention relates to a reactive-reactor for a transport polymerization (“TP”) process module, wherein the process module is useful for the deposition of low dielectric (“ε”) thin films in IC manufacture. The reactive-reactor has reactive interior surfaces for effective conversion of precursors to intermediates. The resultant reaction products of the precursor and the interior surface material of the reactive-reactor are very stable, and do not cause metallic contamination of the semiconductors. Furthermore, the reactive-reactor is also equipped with Reactor Re-generating capacity, which makes it suitable for use in the process module system disclosed in the co-pending patent application, entitled “Process Modules for Transport Polymerization of Low ε thin films,” with U.S. Ser. No. 10/126,919. This pending application was filed on Apr. 19, 2002 with Lee, et al. listed as inventors, and is hereby incorporated by reference.

One aspect of the current invention is the reactive-reactor. In a preferred embodiment, the reactive-reactor comprises: a vacuum vessel with a precursor-gas-inlet for receiving the precursor, a Reactor Re-generating Subsystem (“RRS”) inlet on the vacuum vessel for receiving a reactive gas, and a gas-outlet for discharging an intermediate from the reactive-reactor. The reactive reactor also contains a heater body within the vacuum vessel that is capable of contacting the precursor. Other components of the reactive reactor include: a thermal source with a thermal couple to regulate the temperature of the thermal source and a metal reactant. The metal reactant of this invention is a metal that is capable of generating a chemical reaction between a leaving group on a precursor and the metal reactant. In one aspect of the current invention, the metal reactant comprises a transition metal or noble metal of an interior surface, or portion of the interior surface of the reactive-reactor. In preferred embodiments, the noble metals are Au or Pt, and the transition metals are Ti, Co, Ni, Cr or Fe.

The reactive-reactor of this invention has a very high surface-to-volume ratio, which makes it very compact. For example, in a preferred embodiment, the heater body has a total surface area of at least at least 500 cm and an internal volume of about 40 cm³ for coating wafers of 200 mm with one μm thickness of low dielectric thin film with a transport polymerization (“TP”) process module. Additionally, the heater body comprises a plurality of alternating heating zones and mixing zone. The design of the alternating heating and mixing zones have been contemplated by the inventors to show spiral orientation and multiple heating fins in preferred embodiments. An alternate heater body design comprises spherical closely packed balls (“CPB”), wherein the CPB comprise a diameter that ranges from 0.5 mm to 10 mm, and the CPB are packed with a packing density (“φ”) in the range from about 50% to about 74%. In a preferred embodiment, the CPB comprise the metal reactant. Other preferred heating bodies include porous metallic disks, and metallic disks with small holes. The surface material on the alternating heating elements has also been contemplated to be Pt, Au or a transition metal.

The thermal source of this invention is selected from a group consisting of an infrared heater, an irradiation heater, a thermal resistive heater, a plasma heater, and a microwave heater. In one preferred embodiment, the vacuum vessel is manufactured from an IR transparent material (e.g. quartz or sapphire), wherein the heater body can adsorb sufficient IR radiation to achieve uniform temperatures ranging from 300° C. to 700° C. Additionally, the interior surface material of the reactive-reactor has an effective reaction temperature (“Tr”) with the precursor, wherein the effective Tr between the precursor and the interior surface material of the reactor is below 800° C. when under a vacuum when the vacuum ranges from 0.001 to 200 mTorr. In a preferred embodiment, the interior surface material of the reactor forms a metal halide following exposure with the precursor at the effective Tr. However, the metal reactant can be re-generated from the metal halide at a re-generating temperature (“Trg”), when the Trg is up to, and including 400° C. above the Tr, and the metal halide comprises a melting temperature (“Tm”) in the range of 100 to 400° C. higher than the Tr.

In another aspect of the current invention, a method of generating an intermediate from a heated-precursor using the reactive-reactor is disclosed. The method includes: creating a vacuum in the vacuum vessel; heating the heater body to a reaction-temperature (“Tr”) with the thermal source, to form a heated-heater body; introducing the precursor into the vacuum vessel through the precursor-gas-inlet; warming the precursor with the heated-heater body, to form a heated-precursor; contacting the heated-precursor with the metal reactant, to form the intermediate; and discharging the intermediate from the reaction-reactor. This method is useful for producing a dielectric thin film used in the production of integrated circuit fabrication (“IC”). The temperature in the reactive-reactor is lowered due to the presence of the metal reactant within the reactor. Consequently, the metal reactant becomes a reacted-metal reactant that is incapable of producing more intermediates from precursors at the specified Tr. In order to restore the metal reactant, method comprising a Reactor Re-generating Subsystem (“RRS”) is also disclosed. The method to restore the metal reactant comprises removing organic residues and recovering the metal reactant, if the metal reactant is not a noble metal.

The method of removing the organic residues from a reacted-metal reactant using the Reactor Re-generating Subsystem (“RRS) comprises: heating the heater body to a cleaning-temperature with the thermal source, to form a heated-heater body; introducing a heated cleaning-gas into the reactive-reactor through the RRS gas inlet; contacting the heated cleaning-gas with the organic residue to give an oxidized gas; and discharging the oxidized gas from the reactor. The cleaning temperature of the preferred embodiment is at least 400° C., and the cleaning gas comprises pressurized oxygen with a pressure of about 1 to 20 Torr. In another embodiment, the cleaning gas is pressurized air. Note that during this cleaning process, the reacted-metal reactant will become an oxidized-metal reactant, if the metal-reactant is not a noble metal.

To recover the metal-reactant from the oxidized-metal reactant comprises heating the heater body to a re-generating-temperature with the thermal source, to form a heated-heater body; introducing a re-generating-gas into the reactive-reactor through the RRS gas inlet; contacting the re-generating-gas with a oxidized-metal reactant forming an reductive-gas and the metal reactant; and then purging the reaction-reactor with an inert gas. In a preferred embodiment, the metal reactant comprises an interior surface material of the reactive-reactor, and the reacted-metal reactant comprises a metal halide. The re-generating gas in the method comprises about 1 to 50% of hydrogen in an inert gas such as argon with about 1-20 Torr of pressure. The regenerating temperature (“Trg”) of the method is equal to or less than 400° C. above a reaction-temperature of the metal reactant and the precursor. The oxidized-gas formed from the preferred method is a halogen and the metal reactant is regenerated.

### BRIEF DESCRIPTION OF THE DRAWINGS

FIG. 1 shows the four main components of a conventional deposition system for transport polymerization;

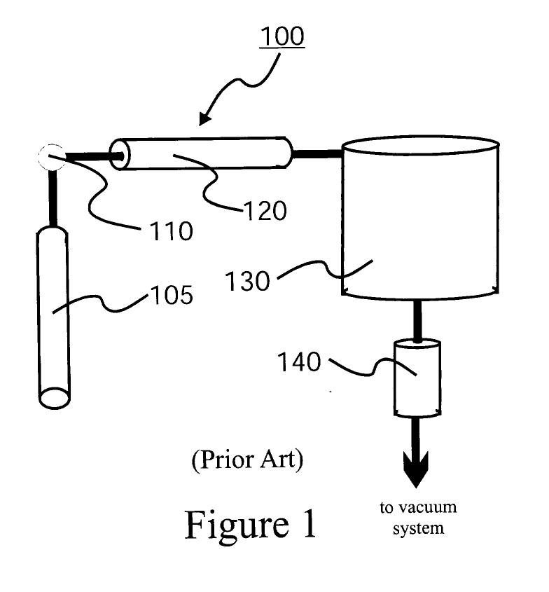

FIG. 2 shows a chart of metal bromides and their corresponding melting points;

FIG. 3 shows an illustration of a reactive-reactor that uses radiation as primary energy source for the heater elements inside the reactor;

FIG. 4 shows a cross-section view of a reactive-reactor, there is a gap between the reactor vessel wall and the inside heater elements;

FIG. 5 shows a 3 dimensional view for spiral-aligned heater elements and a center core for adsorbing the radiation; and

FIG. 6 shows a 3 dimensional view for different spiral-aligned heater elements and a center core for adsorbing the radiation.

### DETAILED DESCRIPTION OF PREFERRED EMBODIMENTS

Terms:

A “metal reactant” as used herein is a metal capable of generating a chemical reaction between a leaving group of a precursor and the metal reactant. In one aspect of the current invention, the metal reactant comprises an interior surface, or portion of the interior surface of the reactive-reactor.

A “reacted-metal reactant” as used herein is a metal that has reacted with a precursor to generate a desired intermediate. In one aspect of the current invention, a reacted-metal reactant comprises a metal halide (e.g. metal bromide). In another aspect of the current invention, the reacted-metal reactant is a metal halide on an interior surface of the reactive-reactor. Although not wanting to be bound by theory, there are two types of metal bromides. One that will decompose below the reactor temperature, and thus it's metal is “catalyst-like,” because the metal surface will be self-regenerated under the operation temperature of the reactor. The other types of metal bromide are very stable, thus regenerating processes are needed to bring the surface back to the pure metal for further reaction to generate the intermediate.

A “regenerating temperature” as used herein is a temperature capable of regenerating a metal reactant from a reacted-metal or used metal reactant.

A “regenerating gas” as used herein is a gas capable of regenerating a metal reactant from a reacted-meal or used metal reactant. In one aspect of the current invention, a regenerating gas (i.e. hydrogen and argon) is used to regenerate a metal reactant from a metal halide. In another aspect of the current invention, a regenerating gas is used to regenerate a metal reactant from an oxidized-metal reactant.

Chemical Principles: Instead of using thermolysis or photolysis to crack the dimmer or precursors, the preferred embodiment of the present invention comprises specially selected metallic interior surfaces for the reactive-reactor to facilitate new precursor chemistries and special chemical processes to re-generate the reactive surfaces. The reactive-reactor needs to generate useful reactive intermediates with high efficiency and low side-reaction product from precursors that have a general chemical structure as shown in formula (VI).

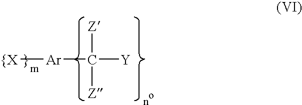

Wherein, n^{o} or m are individually zero or an integer, and (n^{o}+m) comprises an integer of at least 2 but no more than a total number of sp²C-X substitution on the aromatic-group-moiety (“Ar”). Ar is an aromatic or a fluorinated-aromatic group moiety. Z′ and Z″ are similar or different, and individually a hydrogen, a fluorine, an alkyl group, a fluorinated alkyl group, a phenyl group or a fluorinated phenyl group. X is a leaving group, and individually a —COOH, —I, —NR₂, —N⁺R₃, —SR, —SO₂R, wherein R is an alkyl, a fluorinated alkyl, aromatic or fluorinated aromatic group, and Y is a leaving group, and individually a —Cl, —Br, —I the Br and I are preferred. Furthermore, the aromatic is preferably a fluorinated aromatic moiety including, but not limiting to, the phenyl moiety, —C₆H₄₋ₙFₙ (n=0 to 4) such as —C₆H₄— and —C₆F₄—; the naphthenyl moiety, —C₁₀H₆₋ₙFₙ— (n=0 to 6) such as —C₁₀H₆— and —C₁₀F₆—; the di-phenyl moiety, —C₁₂H₈₋ₙFₙ— (n=0 to 8) such as —C₆H₂F₂—C₆H₂F₂— and —C₆F₄—C₆H₄—; the anthracenyl moiety, —C₁₂H₈₋ₙFₙ; the phenanthrenyl moiety, —C₁₄H₈₋ₙFₙ—; the pyrenyl moiety, —C₁₆H₈₋ₙFₙ— and more complex combinations of the phenyl and naphthenyl moieties, —C₁₆H₁₀₋ₙFₙ—. Note that isomers of various fluorine substitutions on the aromatic moieties are also included in this invention.

The functional requirements for a reactive-reactor are largely determined by chemical structure of leaving groups X and Y and chemical methods that used to remove them in the reactor. The leaving groups can be removed from precursors of formula (VI) by several different chemical methods. Traditional methods that generate reactive intermediates under vacuum or under inert atmosphere include, but are not limited to:

irradiation using photons or electrons

cracking using thermal heat,

plasma energy, or

microwave energy.

The intermediates of the present invention are generated by chemical reaction between the leaving group and the interior surfaces of the reactive-reactor. Accordingly, the interior surface material of the reactive-reactor can be selected from the transition metals such as Ni, Pt, Ti, W, Co etc. For instance, a special class of di-bromo precursors (e.g. VIa) can reacted with a transition metal (“M”) inside the interior surfaces of a reactive-reactor with an effective Reaction Temperature (“Tr”) and generate desirable intermediate (e.g. VIb) that is useful for transport polymerization and deposition of the low k polymer (VIc) as shown in equation (5):

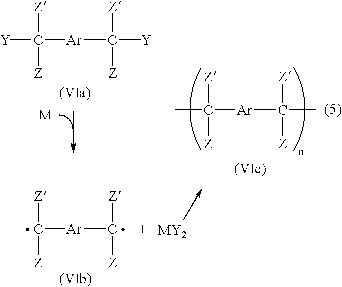

It is understood that the metal halide (“MY₂”) must be re-generated to make the reactive-reactor useful for further conversion of precursors (e.g. VIa) into intermediates (e.g. VIc). This can be done by a reductive reaction with an effective Regenerating Temperature (“Trg”) according to the following reaction (6):

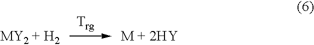

Wherein M is a transition metal (e.g. Ni), and Y═Cl, Br or I. In a preferred example when the metal halide (i.e. M═Ni and Y═Br) is at a temperature of 500° C., Enthalpy (“dH”)=−130.4 kJ/mol; Gibb's Energy (“dG”)=20.3 kJ/mol; and k=4.23E−2.0 for the reaction (6). It is noteworthy that that H₂ and HY are all in a gas phase. Similarly, the metal halide (“MY₂”) can be regenerated by a decomposition temperature (“Td”), according to the reaction (7):

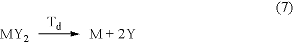

To generate sufficient amount of intermediates and dielectric film for the manufacturing of IC application, the reactive-reactor is equipped with sufficient Metal (“M”) on the interior surfaces of the reactor, so that sufficient number of reaction (1) can occur before re-generation reactions (6 and 7) are needed.

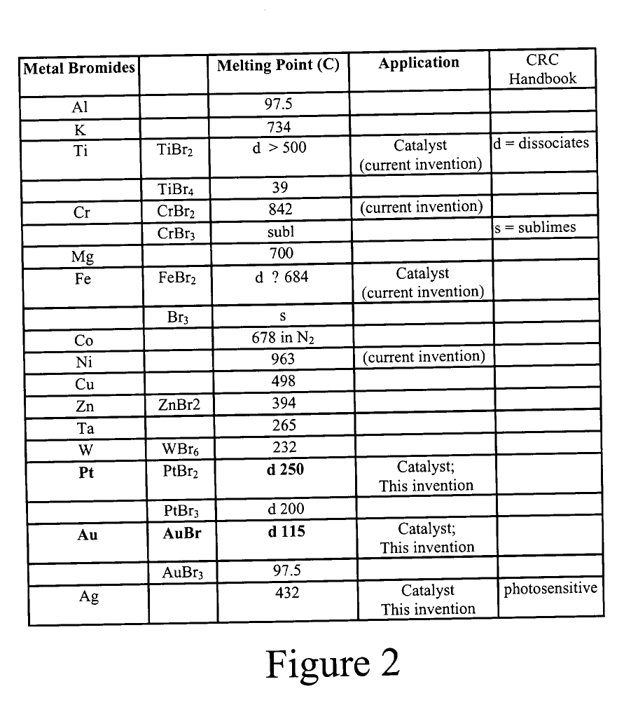

To be useful for the present invention, following four criteria are employed to select an appropriate metal as the interior surface material of the reactive-reactor: First, the effective reaction temperature (“Tr”) between the precursor and the metal should be under 800° C. (and preferably 700° C.), under a vacuum ranging from 0.001 to 200 mTorrs. Herein, the Tr is defined as the temperature at which an effective amount of the intermediates can be generated over a period of few minutes for useful application of the reactive-reactor in the manufacturing IC environment. Second, in one aspect of the current invention, the Td is equal or lower than the effective Tr. Although not wanting to be bound by theory, under this ideal condition, the metal is a catalyst. Third, the preferred re-generating temperature (“Trg”) for the metal halide (“MY₂”) is above the Tr, however, the Trg should not be more than 400° C. (and preferably not more than 200° C.) above the Tr. However, when Trg=Tr, the reactor can be set at Tr and re-generating of reactive-reactor can be done at the same temperature by using on the Reactor Re-generating Subsystem. Fourth, the melting temperature (“Tm”) of the metallic halide (“MY₂”) needs to be at least 100 to 200, preferably 300 to 400° C. higher than the Tr. A metallic halide (“MY₂”) that has a low melting temperature (“Tm”) is not stable inside the reactive rector thus tends to migrate or diffuse outside the reactor and contaminate the equipment or the semiconductors. The melting temperature (“Tm”) of some transition metals such as Ti, Fe, Pt, Cr, Co and Ni are listed in the chart of FIG. 2, and useful for the current invention.

Because Au and Pt reactants are self-regenerated at temperatures above the Td (e.g. 115 and 250° C., respectively) of their reaction products AuBr and PtBr₂, Au and Pt are the preferred reactant, and are useful for practice of this invention when using a di-bromo precursor (VIa). In addition, since the Pt and Au are Noble metals, organic residue inside the reactive-reactor can be removed using oxidative process without causing the oxidation of the Au and Pt. For example, a reactive-reactor with Pt interior surfaces operated at temperatures from 280 to 400° C. promotes “coke” formation or “carbonization” of precursors at a relatively low rate. Passing oxygen through the reactive-reactor and then purging with nitrogen will remove organic residue from inside the reactor.

Iron (“Fe”) and Ti are suitable transition metal reactants for di-bromide precursors (e.g. formula VIa in equation (5), wherein Y-CZZ′-Ar-CZZ′-Y, and Y═Br). One reason this is that the reactive-reactor can be operated at temperatures around 680 to 700° C. and 500 to 550° C., which are near the respective decomposition temperatures (“Td”) of Fe- and Ti-bromides. However, it is important to take note that when reactor temperatures are maintained above 500° C. over time, “coke” formation can be expected. Consequently, oxidative decomposition of an organic residue is needed when Fe or Ti transition metal reactants are used. In contrast, when Cr, or preferably Ni is selected as the interior surface materials, since Ni will react with a di-bromines precursor such as (Y-CZZ′-Ar-CZZ′-Y, Y=Br) at temperatures (Tr) above 480° C. The Nickel bromide can be effectively reduced to nickel using a minimum of 4 to 10% of hydrogen in Argon. The re-generating temperatures (“Trg”) ranging from 500 to 650° C. for few minutes. Since the Nickel Bromide has a melting temperature (“Tm”) as high as 963° C., thus it is very stable inside the reactor during the de-bromination (Reaction (5)) and re-generation reactions (Reaction (6)). However, the Ni tends to oxidize when oxygen is used to oxidize the organic residues inside the reactive-reactor. One way to extend the life span of the Ni-reactor is to use the reactor at about 480° C. for generation of intermediates from the dibromo-precursors(VIa) and then re-generate the Nickel from the Nickel bromide at 600° C. or above using hydrogen. At 480° C., the coke formation rate is relatively low if the reactor is design properly and the residence time of the precursor is short. To improve the throughput of this type of reactive-reactor, normally multi-reactors are employed for a deposition system. Therefore, during generation of intermediate and deposition of low k film, some of the used reactors can be re-generated. In addition, the effective operation time of a reactor before cleaning of the organic residue can be largely extended using the reactor designs shown in the following.

On the other hand, Ag is not a practical reactant for a reactive-reactor, since intermediates needs to be generated at temperatures (Tr=200 to 350° C.) that are too close to the Tm (e.g. 450° C.) of the Silver bromide reaction products. Similarly, Co, Al, Cu, W and Zn are not preferred as the interior surface materials because the Tm of the corresponding bromides is too low or too close to the reactor temperature, which tends to migrate and diffuse into the deposition chamber. However, Silver coating inside a light transmitting reactor wall and heater elements can be useful for the current invention. The reactor temperature (“Tr”) can be at 250° C., whereas silver can be re-generated by exposing the silver Bromide to high intensity of visible light. Alternatively, many metals can be re-generated by exposing its metal bromides to UV light via photolytic reaction, thus are useful as interior surface material for the reactor of this invention.

Furthermore, multi-reaction steps can be used to re-generate the metal reactant for further reaction (5). These are shown in the following reactions (8) and (9):

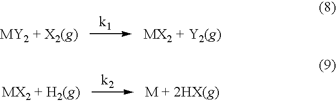

wherein M is a transition metal (e.g. Ni), and Y=Cl, Br or I and X is fluorine. In a preferred example when the metal halide is M=Ni, Y=Br and X=F at 500° C., dH=−416 kJ/mol; dG=−398 kJ/mol; and k₁=8.2E26 for the reaction (8); and dH=106 kj/mol, dG=−17.7 kj/mol and k₂=1.6E1.0 for the reaction (9). It is noteworthy that that X₂, Y₂, H₂ and HX are all in a gas phase.

In a preferred example, a two-reaction method to restore the metal reactants are shown in reactions (10) and (11) as follows:

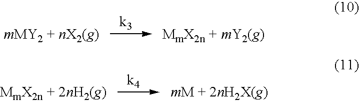

wherein, M is a transition metal such as Ni, Y is Cl, Br or I and X is oxygen. For example, when M═Ni, X═O, Y═Br, m=1, n=1 at 500° C., the dH=0.33 kJ/mol; dG=−31.33 kJ/mol and k₁=1.29E2 for the reaction (10); and dH=−9.2 kj/mol, dG=-35.2 kj/mol and k₂=2.39E2.0 for the reaction (11). When M═Fe, X═O, at 600° C., m=2, n=1.5, dH=−271 kj/mol, dG=−250 kj/mol and k₃=9.8E14 for reaction (10); and dH=69.4 kj/mol, dG=−5.3 kj/mol and k₄=2.06 for reaction (11). It is noteworthy that X₂, Y₂, H₂ and HX are in a gas phase.

By comparing the above reactions (e.g. reactions (8), (9), (10), and (11)) to reaction (6), one observes that the multi-reactions chemistries are kinetically more suitable for cleaning the reactor of this invention due to their high reaction constants. It is also noteworthy that an end point detector (e.g. a Residual Gas Analyzer (“RGA”)) can be used to determine the completion of reactions (10) and (11) by monitoring the contents of the bromine (reaction 10) and water (reaction 11).

Because the TP processing using such reactive-reactor may leave an organic residue inside the interior surfaces of the reactor, the oxidative reaction (10) is needed to clean the organic residue using the Reactor Re-generating Subsystem (“RRS”). The method for cleaning the organic residue comprises: heating the heater body to a desired temperature with an energy source; introducing a oxygen into the reactive-reactor through the RRS gas inlet; burning the organic residue with the heated gas to give an oxidized gas; and discharging the oxidized gas from the reactor. During the cleaning process, the inside temperature of the reactive-reactor is at least 400° C. The heated gas supply used to clean the reactive-reactor is pressurized oxygen, in the range from about 1 to 20 psi. However, after cleaning the organic resides, the metal halide, MY₂ of the interior surfaces of the reacted-reactor will also changed to metal oxide, MX by the oxidative reaction (10), thus a subsequent reductive gas, such as hydrogen, is needed to restore the metal, M, by a reductive reaction (11). Other reducing agents that can be used for the reductive reaction (11) are ammonium hypophosphite, hydrazine and borohydride. In this later case, these reducing agents can be dispensed inside the reactor as an aqueous solution or pure liquid agent.

The above examples are offered by way of illustrations for the applications of the selection criteria revealed in this invention, and are not intended to limit the scope of the invention in any manner. One skilled in the art will appreciate that the material selection criteria for the reactive-reactor can be easily applied to other transition metals and Noble metals.

The material selection criteria revealed in this invention can be applied to all TP reactors described in the co-pending patent applications by Lee, et al, including U.S. patent application Ser. No. 10/125,626 filed in Apr. 17, 2002, and entitled “Multi-stage-heating Thermal reactor for transport Polymerization” with Lee, et al. listed as inventors, (“the Lee '626 Patent”); U.S. patent application Ser. No. 10/126,919 filed in Apr. 19, 2002 entitled “Process Modules for transport polymerization of low ε thin films” with Lee, et al. listed as inventors(“the Lee '919 Patent”); and U.S. Patent application Ser. No. 10,141,358 filed on May 9, 2002 and entitled “Thermal reactor for transport Polymerization of low k thin film” with Lee, et al. listed as inventors (“the Lee '358 Patent”). It is also noteworthy that all previous TP reactors disclosed by Lee, et al., are based on thermolysis and photolysis of precursors for the generation of the intermediates that are useful for Transport Polymerization. The interior surfaces of all prior reactors are non-reactive or inert toward precursors. Additionally, the reactors of the Lee '626-, Lee '919-, and Lee '358-Patents are all based on the thermolysis of precursors, and have their heater elements inside the reactor to be heated primarily by thermal conduction or radiation.

Examples for Reactive-Reactor Designs: The preferred reactive-reactor design of the current invention incorporates the chemical properties of the precursor material. For example, the gas reactor will react with the selected precursors and generate intermediates and other side products at low pressure. The inside of the reactive-reactor is made of high purity materials that are reactive toward the selected precursors. The reactor relies on thermal energy (i.e. temperature) to carry out the reaction (5). The preferred reactive-reactor may need re-generation via reactions (6) and (7) after the reaction (5). To re-generate the metallic surface from the metallic bromide by the reaction (6), hydrogen in Argon is fed through a mass flow controller (“MFC”) and a valve into the reactive-reactor. The resulting products (mainly Hydrogen halide and other small organic compounds) can be pumped directly to the exhaust through the reactor by-pass line and valve. Accordingly, a reactive-reactor has an inlet for precursor and an outlet for reaction products that generated from the reactor. In addition, the outlet also has a bypass for injection of hydrogen for the reaction (6) and its inlet has a bypass for exhaust of reaction products. Furthermore, it may also need an oxidative cleaning after a specified period of film depositions. The oxidative cleaning can be accomplished by burning the organic residues inside the reactor in the presence of oxygen. Alternatively, a ceramic reactor can be also cleaned using oxidative plasma in conjunction with a plasma-cleaning device.

In a preferred embodiment of this invention, a thermal or photo-assisted thermal reactions between the interior metallic surfaces and the precursors are employed to generate useful reactive intermediates from precursors (VI) described in the above paragraphs. Therefore, a TP reactive-reactor is comprised of a heater and an inside heater elements to react with precursors and an outside container for keeping the inside heater body under vacuum condition. Details of the material selection, heating methods, and heater body designs are discussed in the below paragraphs. The heater body and heater element are used as interchangeable terms.

Material Selections: The preferred materials selected for the container wall (i.e. vacuum vessel wall) of the reactive-reactor are selected and manufactured from a group of transition metals including but not limiting to Ni and its alloys such as Monel and Inconel, Pt, Cr, Fe and especially Stainless Steel, and preferably the noble metals including, but not limited to, Pt and Au. Nonmetallic materials can also be used to construct the heater, then the inside surfaces of the heater shall be coated with selected metallic materials of this invention. The nonmetallic materials include but not limited to quartz, sapphires or Pyrex glass, Alumina Carbide, Al₂O₃, surface fluorinated Al₂O₃, Silicon Carbide, Silicon Nitride, and Silicon Carbide. The heater body can be constructed from these metallic or ceramic media with pores or in the shapes of small tubes, heating fins or spherical balls.

Heating Methods: The reactive-reactor can be heated by several methods. However, in preferred embodiments of the present invention, a resistive heater and an infrared (“IR”) heater are used. When a resistive heater is used, the inside heater body may have physical contact(s) with inside wall of the reactive-reactor. When the inside heater body has physical contact with the resistive heater, the inside heater body is heated primarily via conductance and some radiation and the heater body needs to have excellent thermal conductivity to maintain uniform temperature inside a vacuum. Without a proper design to take advantage of the radiation effect, the inside heater body will have high temperature variation especially if the heater body has poor conductivity. On the other hand, a special design is used and illustrated in this invention so that the inside heater body or heater elements are primarily heated by radiation and very uniform temperature inside the Reactive heater is achieved. In this preferred embodiment of the present invention, radiation provides the energy to heat the heater-bodies inside the reactive-reactor under vacuum.

An infrared (“IR”) heater or microwave was used for heating the reactor. In U.S. Pat. No. 6,140,456 with Chung Lee, et al listed as inventors (“the Lee '456 patent”), IR was used to crack precursors passing inside a vacuum quartz tube. The Lee '456 patent provides teachings that under few mTorrs of vacuum, IR is not effective due to the extremely short residence time of precursors inside the reactor. Additionally the Lee '456 patent utilized microwave energy to generate plasma for transport polymerization. However, as was noted above plasma polymerization is not suitable for making useful low k of this invention. However, an IR heater can be used to heat the heater body or heater elements inside the reactive-reactor. The heater elements then react with the precursors to generate the intermediates according to reaction (5).

Tungsten Halogen lamps are part of a preferred embodiment for an IR heater of the current invention. When an IR heater is utilized, the wall of reactive-reactor should use an IR transparent material (e.g. quartz), so that IR can reach the inside heater body. Preferably, the inside heater body is an IR absorbing metals or ceramic material such as Alumina Carbide, Alumina Oxide and preferably Silicon Carbide. The heater body consists of heater elements that can be a porous medium, small tubes, fins or spherical balls. These IR adsorbing elements can be placed as continuous media or be spaced inside the reactor, thus create an alternating heating and mixing zones inside the reactor. This type of reactive-reactor can generate more uniform heating for passing precursors and prevent back diffusion for intermediates. When an employed precursor exhibits strong absorption in the IR ranges for its leaving groups such as halogen and carboxylic acid, photon-assisted thermal cracking can enhance the reactor efficiency.

Alternatively, a resistive heater is used to heat a black body such as Silicon Carbide so the black body can generate IR in the ranges from 700 to 1200 cm⁻¹. In this conjunction, the outside wall of the reactive-reactor should be constructed using a IR transparent material so that radiation can reach the inside of the reactive-reactor.

As an alternative, the outside wall of the reactive-reactor can also be constructed using a metal or ceramic material that is not transparent to IR. For instance, the resistive heater can be mounted directly onto the wall of the reactive-reactor, while heat adsorbing metal or a black body such as SiC is inserted inside the reactive-reactor. In this case, the metal or the black body inside the reactive-reactor is heated to generate IR in the ranges from 700 to 1200 cm⁻¹.

An IR heater can be manufactured from a single heating element of Iron-Chromium-Aluminum or Nickel-Chromium coil. This type of IR heater can ramp up in 10 to 20 second and has up to 60 Watts/in or higher of power; while a double wounded heating coil can ramp up in 5 seconds. In addition, a lamp consists of Tungsten filaments in vacuum or in the presence of Halogen can be used as IR heater for this invention. This type of IR lamp can provide up 60 Watts/in² to 200 Watts/in² or higher of power and can ramp up in 1-2 seconds, but it also needs air or water-cooling to operate. Commercial IR heaters are available for instance from Solar Products Inc. at Pompton Lakes in New Jersey.

Heater Body: In a thermolytic reactor, precursors gain thermal energy during heating by colliding with the heating elements or heater bodies inside the reactive-reactor. Once a precursor molecule acquires sufficient thermal energy to meet or exceed the energy of activation, thermal cracking or breakage of the chemical bonds occurs. However, in the present reactive-reactor, the interior surface metal can react with the precursor at much lower temperatures. For instance, it is known that iron will react with the dibromo precursor (e.g. VIa) when the interior Iron surface temperature reaches about 420° C., whereas copper needs only 320 to 350° C. under the similar vacuum condition of few mini Torrs. A pure themolytic reaction for the precursor would need 680° C. under similar conditions or when an inert interior surface material is used for the same reactor designs. It is important that the heater body provides a sufficient surface area for the precursors to collide as they are transported through the reactive-reactor. Although not wanting to be bound by theory, the reaction rate is proportional to the surface area under the same Tr. In a preferred embodiment of the present invention, the volume of the reactive-reactor is less than 60 cm³, and the surface area of the heater body is at least 300 cm², preferably 500 cm². Additionally, the reactor should be built to hold a vacuum under 0.01 to 1 mTorr. Several methods are used to increase the surface areas of the inside heater body, including, but not limited to: a porous medium; small tubes; heating fins; or spherical balls. Ideal porous heater bodies should have skeletal structure and their skeletal wall consist of no void, no inclusion, and no entrapment or metallic impurity. A porous medium is particularly useful for this invention if it has reticular structure of open, duode-cahedronal-shaped cells connected by continuous solid metal or ceramic ligaments. Its matrix of cells and ligaments are completely repeatable, regular and uniform throughout the entirety of the medium. These porous media have good thermal conductivity and structure integrity. It is rigid, highly porous and permeable and has a controlled density or ceramic per unit volume. Density of useful media for this invention varies from 5 to 90%, preferably from 30 to 50% for a combination of high permeability and thermal conductivity. Cell size can be from 5 to 150, preferably from 20 to 60 ppi (pores per inch) that has mean pore size from 5 mm to 0.12 mm, preferably from 1 to 0.3 mm. These porous media have high surface areas to volume ratio ranging from 10 to 80 cm²/cm³, thus compact reactors be fabricated for this invention. Porous reactor of monolithic entity that has low heat-contact resistance between its heating element and heating body (porous ceramic) is useful for this invention.

When porous heater bodies are used, the inside diameter of pores should range from 0.01 to 5 mm, preferably 0.5 to 3 mm. Although not wanting to be bound by theory, when the inside diameter, Φi of these pore is less than the mean-free-path (“MFP”) of the precursors, more collision between the precursors and inside surfaces of the heater bodies can be expected. The MFP can be easily calculated by engineers that are skillful in the state of art, thus needs no additional description here. However, when the pore size is too small, excess surface areas in gas flow or diffusion direction can generate too many collisions between precursors or their reaction products with the heater bodies inside the reactor. When pore sizes are much smaller than the MFP of these chemicals, forward diffusion of these chemicals can be impeded (“Gas Choking”) and coke formation becomes a serious problem under high reactor temperatures.

Gas choking of reactive intermediates or other reaction products inside the reactor can create excess coke formation due to long exposure of these chemicals at high temperature, and should be avoided during the designing of the reactor. One way to avoid this is a multiple-zone heater design, for instance, having a preheating and a cracking zone. Inside a preheating zone, the precursors will have limited conversion to intermediates due to a lower zone temperature. Once the precursors in the pre-heater reaching to a desirable temperature and pressure, the heated precursors can then be quickly released into a second heating zone for reaction. Using this two-zone heater, the reaction efficiency can be largely increase, but avoid excess carbon formation inside the reactor. By reducing heating path and temperature variation in the cracking zone of a reactor, chemical conversion efficiency can be maximized with lower amounts of carbon formation. Thus, when a multiple-zone reactor is used, the heater bodies in the pre-heating zone should consist of smaller pores, whereas the cracking zone should use bigger pores.

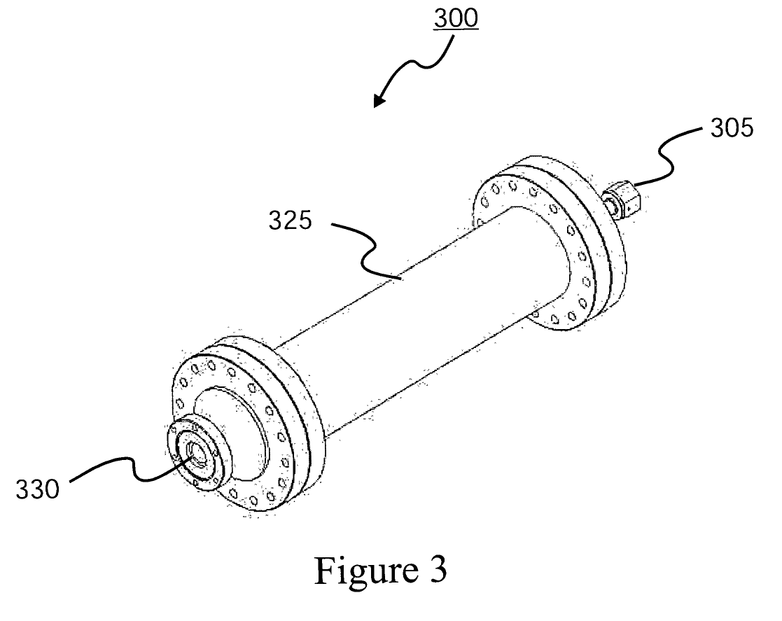

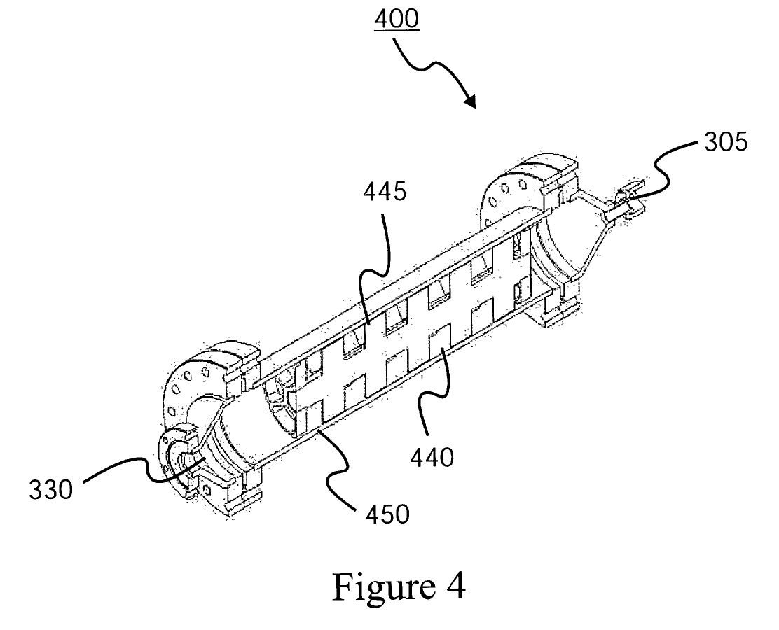

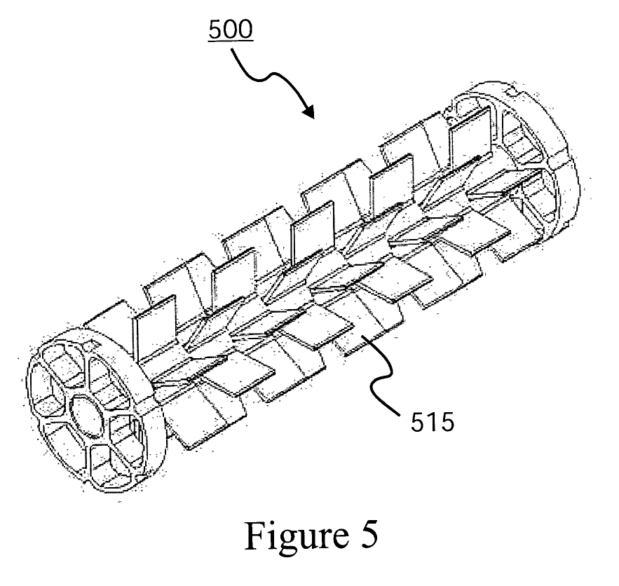

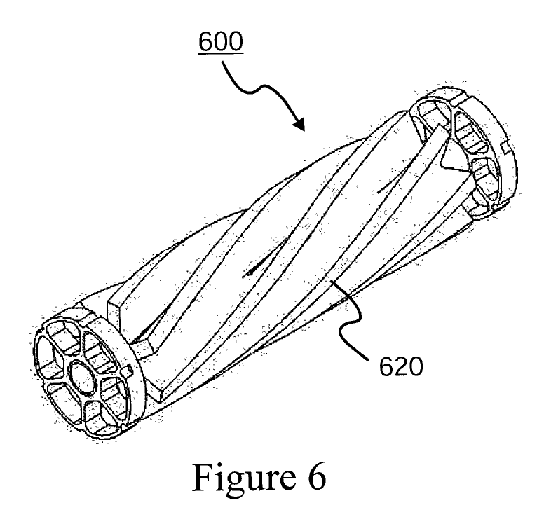

Preferred Reactor Designs: The reactive-reactor can be in any shape or configuration as long as its temperature Tr and pore size and surface area meeting the requirements mentioned in the above. The reactor shown in the FIG. 3 illustrates applications of the above teachings. The reactive-reactor contains a precursor inlet 305, and a reactive intermediate outlet 330. When an IR heater is used, the wall 325 of the reactive-reactor should use an IR transparent material such as quartz, so that radiation can reach the heater elements inside of reactive-reactor. The inside heater elements 515 (FIG. 5) and 620 (FIG. 6) can be constructed from selected metals of this invention. These metallic heater elements are spaced inside the reactor to create an alternating heating 440 and mixing zones 445, inside the reactor as shown in FIG. 4 for a cross-section view. FIG. 4 also shows a gap between the heater elements and the reactor wall. Thus, the inside heater elements 515 and 620 shown in the FIG. 5, and FIG. 6 are heated primarily by the radiation. Additionally, the heater elements 515, and 620 can be porous metal heater bodies.

To meet the strict requirements of temperature uniformity with the reactor reaction zone and the high conversion rate of precursors (>99%), heat transfer as well as mixing within the reactor must be carefully determined and optimized. At the elevated reaction temperature (>500° C.), the dominant heat transfer mechanism for the above reactor is thermal radiation since the gas loading is negligible. The above reactor includes four assembly parts: the vessel wall (“VW”), the heater elements (“HE”), the inlet diffuser (“ID”) and the outlet nozzle (“ON”). VW is heated to a specified temperature and HE is heated purely by radiation from the inner surface of VW. In this reactor, the conduction through gas is proportional to the gas pressure and distance between VW and HE and is negligible. In addition, the radiation heat transfer with ID and ON is negligible as well as convection effects are minimized and are negligible. The ON is so designed to optimize the reactor residence time and the ID is to diffuse precursor evenly within the volume of the Reaction Zone. The alternating-fin design on the HE promotes turbulence and enhances gas mixing. The advantages of this design include:

(1) The temperature within the reaction zone is much more uniform in both the transverse and longitudinal directions of the reactor.

(2) Gas mixing is maximized to increase conversion rate.

Alternatively, when the reactor wall 325, of FIG. 3, is not an IR transparent material, but a metal selected for this invention, the inside heart body is also primarily heated by adsorbing the radiation heat from the heater wall. The above design can ensure that precursors will not be over heated on the reactor wall and form excess carbon. Carbon formation of the reactor will reduce the heat transfer and make the reactor unsuitable for application over time. Alternatively, a resistive heater can heat a reactive-reactor of this invention.

The Reactor Regenerating Subsystem (“RRS”): Because a reactive-reactor may need periodic regeneration of its interior surfaces or/and to remove residual organic chemicals that become trapped inside the reactor, a reactive-reactor needs to be equipped with a Reactor Regenerating Subsystem (“RRS”). The preferred RRS of the current invention is connected to the reactor and is by-passed to a sewage deposit tank or gas scrubber system. There are many different methods can be used to regenerate the interior metal surfaces or/and clean reactive-reactor that contains organic residue, some of these methods are:

(1) A RRS can employ a hydrogen gas, preferably from 3 to 50% of hydrogen in an inert gas such as Nitrogen or Argon as re-generating gas. A H/Ar gas mixture is injected into a de-activated reactive-reactor to achieve from 1 to 5, preferably 5 to 20 Torrs of pressure. For instance, the Nickel bromide can be re-generated at 600° C. using 4% hydrogen in Argon for about 10 minutes under the gas pressure of 3 to 5 psi, preferably 5 to 20 psi.

(2) A RRS can also connect to a pressurized oxygen cylinder. To clean organic residue inside the reactor, 1 to 5 psi, or preferably from 5 to 20 psi of oxygen is injected into the reactor at high temperatures. The reactor temperature should be at least 400° C., and preferably 600° C. to reduce the cleaning time. Alternatively, a ceramic reactor can be also cleaned using oxidative plasma.

Additionally, to prevent film deposition inside the gas line between the reactive-reactor and the deposition chamber, the gas line and chamber wall temperatures should be at least 25 to 30° C., preferably 30 to 500 C. It is important to note that the examples of the RRS systems are for a single deposition chamber for a single reactive-reactor. It should be appreciated by those of ordinary skill in the art that other embodiments may incorporate the concepts, methods, precursors, polymers, films, and devices of the above description and examples. The description and examples contained herein are not intended to limit the scope of the invention, but are included for illustration purposes only. It is to be understood that other embodiments of the invention can be developed and fall within the spirit and scope of the invention and claims. For example, all of the above discussions assume a single reactive-reactor per one deposition chamber; however, those who are skillful in tool designs can easily apply the above principles to make a larger reactive-reactor for industrial cluster tools that have multi-deposition chambers.

What is claimed is:

1. A reactive-reactor comprising:
(a) a vacuum vessel with a precursor-gas-inlet for receiving a precursor, and a gas-outlet for discharging an intermediate from the reactive-reactor;
(b) a heater body within the vacuum vessel capable of contacting the precursor;
(c) a thermal source to heat the heater body, the thermal source comprising a direct or indirect connection with the vacuum vessel;
(d) a thermal couple to regulate the temperature of the thermal source; and
(e) a metal reactant capable of contacting the precursor;
wherein, the reactive-reactor is useful for producing a thin film with a transport polymerization (“TP”) process module.

2. The reactive-reactor of claim 1, further comprising a Reactor Re-generating Subsystem (“RRS”) inlet on the vacuum vessel for receiving a reactive gas.

3. The reactive-reactor of claim 1, further comprising an insulation jacket surrounding the reactive-reactor.

4. The reactive-reactor of claim 1, wherein the precursor has a general chemical structure: 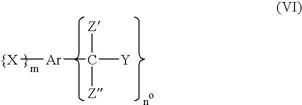
wherein:
Ar is an aromatic or a fluorinated-aromatic group moiety;
n^{o} or m is individually zero or an integer, and (n^{o}+m) comprises an integer of at least 2 but no more than a total number of sp²C-X substitution on the Ar;
Z′ and Z″ are similar or different, and individually a hydrogen, a fluorine, an alkyl group, a fluorinated alkyl group, a phenyl group, or a fluorinated phenyl group;
X is a first leaving group, and individually a —COOH, —I, —NR₂, —N⁺R₃, —SR, —SO₂R, wherein R is an alkyl, a fluorinated alkyl, a halide, an aromatic, or fluorinated aromatic group, and
Y is a second leaving group, and individually a —Cl, —Br and —I.

5. The reactive-reactor of claim 1, wherein the thermal source is an infrared heater, an irradiation heater, a thermal resistive heater, a plasma heater, or a microwave heater.

6. The reactive-reactor of claim 1, wherein the vacuum vessel has an internal volume of at least 20 cm³.

7. The reactive-reactor of claim 1, wherein the heater body has a total surface area of at least 300 cm².

8. The reactive-reactor of claim 1, wherein the vacuum vessel is manufactured from an IR or UV transparent material.

9. The reactive-reactor of claim 8, wherein the IR or UV transparent material is quartz or sapphire.

10. The reactive-reactor of claim 8, wherein the heater body can adsorb sufficient IR radiation to achieve uniform temperatures in the range of about 300° C. to 700° C.

11. The reactive-reactor of claim 1, wherein the heater body comprises a plurality of alternating heating zones and mixing zones.

12. The reactive-reactor of claim 11, wherein the alternating heating zones are in a spiral orientation.

13. The reactive-reactor of claim 11, wherein the alternating heating zones comprise multiple heating fins.

14. The reactive-reactor of claim 1, wherein the metal reactant comprises an interior surface material of the reactive-reactor.

15. The reactive-reactor of claim 14, wherein the interior surface material of the reactive-reactor has an effective reaction temperature (“Tr”) with the precursor.

16. The reactive-reactor of claim 15, wherein the effective Tr between the precursor and the interior surface material of the reactor is below about 800° C. when under a vacuum in the range from 0.001 to 200 mTorr.

17. The reactive-reactor of claim 15, wherein the interior surface material of the reactor forms a metal halide following exposure with the precursor at the effective Tr.

18. The reactive-reactor of claim 17, wherein the metal reactant can be re-generated from the metal halide at a re-generating temperature (“Trg”), the Trg being equal to or less than about 400° C. above the Tr.

19. The reactive-reactor of claim 17, wherein the metal halide comprises a melting temperature (“Tm”), the Tm is in the range from about 100° C. to about 400° C. higher than the Tr.

20. The reactive-reactor of claim 15, wherein the effective Tr is above a decomposition temperature (“Td”).

21. The reactive-reactor of claim 1, wherein the metal reactant is a transition metal.

22. The reactive-reactor of claim 21, wherein the transition metal is Ni.

23. The reactive-reactor of claim 21, wherein the transition metal is Ti, Co, Cr, or Fe.

24. The reactive-reactor of claim 21, wherein the heater body comprises the transition metal.

25. The reactive-reactor of claim 1, wherein the metal reactant is a noble metal.

26. The reactive-reactor of claim 25, wherein the noble metal is Pt or Au.

27. The reactive-reactor of claim 25, wherein the heater body comprises the noble metal.

28. The reactive-reactor of claim 1, wherein the heater body comprises spherical closely packed balls (“CPB”).

29. The reactive-reactor of claim 28, wherein the CPB comprise a diameter that ranges from about 0.5 mm to about 10 mm.

30. The reactive-reactor of claim 28, wherein the CPB comprise the metal reactant, the metal reactant being a transition metal or a noble metal.

31. The reactive-reactor of claim 28, wherein the CPB are packed with a packing density (“φ”) in the range of about 50% to about 74%.

32. The reactive-reactor of claim 1, wherein the heater body comprises a plurality of alternating heating elements and mixing zones, and wherein the alternating heating elements are on a standoff of the heater body arranged in a spiral configuration relative to a direction of overall flow from gaseous precursors in the reactive-reactor.

33. The reactive-reactor of claim 32, wherein the plurality of alternating heating elements are manufactured from a noble metal or a transition metal.

34. The reactive-reactor of claim 32, wherein the plurality of alternating heating elements consists of porous metallic disks.

35. The reactive-reactor of claim 32, wherein the plurality of alternating heating elements comprises of metallic disks with small holes.

36. The reactive-reactor of claim 32, further comprising a surface material on the alternating heating elements, the surface material is Ni, Pt, or Au.

37. The reactive-reactor of claim 32, wherein the heater elements are heated to a temperature of in the range form about 250° C. to about 700° C.

38. A reactive-reactor comprising:
(a) a vacuum vessel with a precursor-gas-inlet for receiving the precursor, a Reactor Re-generating Subsystem (“RRS”) inlet on the vacuum vessel for receiving a reactive gas, and a gas-outlet for discharging an intermediate from the reactive-reactor;
(b) a heater body within the vacuum vessel capable of contacting the precursor;
(c) a thermal source to heat the heater body, the thermal source comprising a direct or indirect connection with the vacuum vessel;
(d) a thermal couple to regulate the temperature of the thermal source;
(e) a metal reactant capable of contacting the precursor, the metal reactant is a transition metal or a noble metal; and
(f) an insulation jacket surrounding the reactive-reactor;
wherein,
the reactive-reactor is useful for producing a thin film with a transport polymerization (“TP”) process module;
the vacuum vessel has an internal volume of at least 20 cm³;
the heater body has a total surface area of at least 300 cm²;
the thermal source is an infrared heater, an irradiation heater, a thermal resistive heater, a plasma heater, or a microwave heater;
the metal reactant comprises an interior surface of the reactive-reactor;
the heater body comprises a plurality of alternating heating zones and mixing zones; and
the precursor has a general chemical structure: 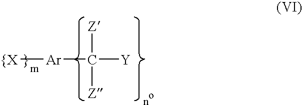
wherein:
Ar is an aromatic or a fluorinated-aromatic group moiety;
n^{o} or m is individually zero or an integer, and (n^{o}+m) comprises an integer of at least 2 but no more than a total number of sp²C-X substitution on the Ar;
Z′ and Z″ are similar or different, and individually a hydrogen, a fluorine, an alkyl group, a fluorinated alkyl group, a phenyl group, or a fluorinated phenyl group;
X is a first leaving group, and individually a —COOH, —I, —NR₂, —N⁺R₃, —SR, —SO₂R, wherein R is an alkyl, a fluorinated alkyl, a halide, an aromatic, or fluorinated aromatic group, and
Y is a second leaving group, and individually a —Cl, —Br or —I.

39. The reactive-reactor of claim 38, wherein the vacuum vessel is manufactured from an IR or UV transparent material.

40. The reactive-reactor of claim 39, wherein the IR or UV transparent material is quartz or sapphire.

41. The reactive-reactor of claim 39, wherein the heater body can adsorb sufficient IR radiation to achieve uniform temperatures ranging from 300° C. to 700° C.

42. The reactive-reactor of claim 38, wherein the alternating heating zones are in a spiral orientation.

43. The reactive-reactor of claim 38, wherein the alternating heating zones comprise multiple heating fins.

44. The reactive-reactor of claim 38, wherein the interior surface material of the reactive-reactor has an effective reaction temperature (“Tr”) with the precursor.

45. The reactive-reactor of claim 44, wherein the effective Tr between the precursor and the interior surface material of the reactor is below about 800° C. when under a vacuum in the range from 0.001 to 200 mTorr.

46. The reactive-reactor of claim 44, wherein the interior surface material of the reactor forms a metal halide following exposure with the precursor at the effective Tr.

47. The reactive-reactor of claim 46, wherein the metal reactant can be re-generated from the metal halide at a re-generating temperature (“Trg”), the Trg being equal to or less than about 400° C. above the Tr.

48. The reactive-reactor of claim 46, wherein the metal halide comprises a melting temperature (“Tm”), the Tm is in the range from about 100° C. to about 400° C. higher than the Tr.

49. The reactive-reactor of claim 43, wherein the effective Tr is above a decomposition temperature (“Td”).

50. The reactive-reactor of claim 38, wherein the noble metal is Pt or Au.

51. The reactive-reactor of claim 38, wherein the transition metal is Ni.

52. The reactive-reactor of claim 38, wherein the transition metal is Ti, Co, Cr, or Fe.

53. The reactive-reactor of claim 38, wherein the heater body comprises the metal reactant.

54. The reactive-reactor of claim 38, wherein the heater body comprises spherical closely packed balls (“CPB”).

55. The reactive-reactor of claim 54, wherein the CPB comprise a diameter that ranges from about 0.5 mm to about 10 mm.

56. The reactive-reactor of claim 54, wherein the CPB comprise the metal reactant.

57. The reactive-reactor of claim 54, wherein the CPB are packed with a packing density (“φ”) in the range of about 50% to about 74%.

58. The reactive-reactor of claim 38, wherein the heater body comprises a plurality of alternating heating elements and mixing zones, and wherein the alternating heating elements are on a standoff of the heater body arranged in a spiral configuration relative to a direction of overall flow from gaseous precursors in the reactive-reactor.

59. The reactive-reactor of claim 58, wherein the plurality of alternating heating elements are manufactured from materials that comprise the metal reactant.

60. The reactive-reactor of claim 58, wherein the plurality of alternating heating elements consists of porous metallic disks.

61. The reactive-reactor of claim 58, wherein the plurality of alternating heating elements consists of metallic disks with small holes.

62. The reactive-reactor of claim 58, further comprising a surface material on the alternating heating elements, the surface material is Ni, Pt, or Au.

63. The reactive-reactor of claim 58, wherein the heater elements are heated to a temperature of in the range from about 250° C. to about 700° C.

64. A method of generating the intermediate from a heated-precursor using the reactive-reactor of claim 2, the method comprising:
(a) creating a vacuum in the vacuum vessel;
(b) heating the heater body to a reaction-temperature (“Tr”) with the thermal source to form a heated-heater body;
(c) introducing the precursor into the vacuum vessel through the precursor-gas-inlet;
(d) warming the precursor with the heated-heater body to form a heated-precursor
(e) contacting the heated-precursor with the metal reactant to form the intermediate; and
(f) discharging the intermediate from the reaction-reactor;
wherein, the intermediate is useful for producing a dielectric thin film used in the production of integrated circuit fabrication (“IC”).

65. The method of claim 64, further comprising an insulation jacket surrounding the reactive-reactor.

66. The method of claim 64, wherein the precursor has a general chemical structure: 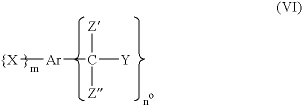
wherein:
Ar is an aromatic or a fluorinated-aromatic group moiety;
n^{o} or m is individually zero or an integer, and (n^{o}+m) comprises an integer of at least 2 but no more than a total number of sp²C-X substitution on the Ar;
Z′ and Z″ are similar or different, and individually a hydrogen, a fluorine, an alkyl group, a fluorinated alkyl group, a phenyl group, or a fluorinated phenyl group;
X is a first leaving group, and individually a —COOH, —I, —NR², —N⁺R₃, —SR, —SO₂R, wherein R is an alkyl, a fluorinated alkyl, a halide, an aromatic, or fluorinated aromatic group, and
Y is a second leaving group, and individually a —Cl, —Br and —I.

67. The method of claim 64, wherein the thermal source is an infrared heater, an irradiation heater, a thermal resistive heater, a plasma heater, or a microwave heater.

68. The method of claim 64, wherein the vacuum vessel has an internal volume of at least 20 cm³.

69. The method of claim 64, wherein the heater body has a total surface area of at least 300 cm².

70. The method of claim 64, wherein the vacuum vessel is manufactured from an IR transparent material.

71. The method of claim 70, wherein the IR transparent material is quartz or sapphire.

72. The method of claim 70, wherein the heater body can adsorb sufficient IR radiation to achieve uniform temperatures ranging from about 300° C. to about 700° C.

73. The method of claim 64, wherein the heater body comprises a plurality of alternating heating zones and mixing zones.

74. The method of claim 73, wherein the alternating heating zones are in a spiral orientation.

75. The method of claim 73, wherein the alternating heating zones comprise multiple heating fins.

76. The method of claim 64, wherein the metal reactant is a transition metal.

77. The method of claim 76, wherein the transition metal is Ni.

78. The method of claim 76, wherein the transition metal is Ti, Co, Cr, or Fe.

79. The method of claim 76, wherein the heater body comprises the transition metal.

80. The method of claim 64, wherein the metal reactant is a noble metal.

81. The method of claim 80, wherein the noble metal is Pt or Au.

82. The method of claim 80, wherein the heater body comprises the noble metal.

83. The method of claim 64, wherein the heater body comprises spherical closely packed balls (“CPB”).

84. The method of claim 83, wherein the CPB comprise a diameter that ranges from about 0.5 mm to about 10 mm.

85. The method of claim 83, wherein the CPB comprise the metal reactant, the metal reactant being a transition metal or a noble metal.

86. The method of claim 83, wherein the CPB are packed with a packing density (“φ”) in the range of about 50% to about 74%.

87. The method of claim 64, wherein the heater body comprises a plurality of alternating heating elements and mixing zones, and wherein the alternating heating elements are on a standoff of the heater body arranged in a spiral configuration relative to a direction of overall flow from gaseous precursors in the reactive-reactor.

88. The method of claim 87, wherein the plurality of alternating heating elements are manufactured from a noble metal or a transition metal.

89. The method of claim 87, wherein the plurality of alternating heating elements consists of porous metallic disks.

90. The method of claim 87, wherein the plurality of alternating heating elements consists of metallic disks with small holes.

91. The method of claim 87, further comprising a surface material on the alternating heating elements, the surface material is Ni, Pt, or Au.

92. The method of claim 87, wherein the heater elements are heated to a temperature of in the range from about 250° C. to about 700° C.

93. A method for using the RRS of claim 2 to restore the metal reactant contaminated with an organic residue in the reactive-reactor, the method comprising:
(a) oxidatively-decomposing the organic residue to give an oxidized metal reactant; and
(b) reducing the oxidized-metal reactant with a reducing-reagent.

94. The method of the claim 93, further comprising purging the reactor with an inert gas before the reducing step is introduced.

95. The method of claim 93, wherein oxidatively-decomposing the organic residue comprising:
(a) heating the heater body to a decomposition temperature with the thermal source, to form a heated-heater body;
(b) introducing a heated oxidant gas into the reactive-reactor through the RRS gas inlet;
(c) contacting the heated oxidant gas with the organic residue and the reacted-metal reactant forming an oxidized gas and the oxidized-metal reactant; and
(d) discharging the oxidized gas from the reactor.

96. The method of claim 95, wherein the decomposition temperature is at least 400° C.

97. The method of claim 95, wherein the heated oxidant gas comprises is an oxygen, a sulfur, or an amino containing compound.

98. The method of claim 97, wherein the oxidant gas has a gas pressure of at least 1 Torr.

99. The method of claim 93, wherein reducing the oxidized-metal reactant comprising:
(a) heating the heater body to a re-generating-temperature with the thermal source, to form a heated-heater body;
(b) introducing a reducing agent into the reactive-reactor through the RRS gas inlet;
(c) contacting the reducing agent with the oxidized-metal reactant, forming an oxidized-agent and restoring the metal reactant; and
(d) purging the reaction-reactor with an inert gas.

100. The method of claim 99, wherein the metal reactant comprises a transition metal.

101. The method of claim 100, wherein the transition metal is Ni.

102. The method of claim 99, wherein the oxidized-metal reactant comprises a metal oxide.

103. The method of claim 99, wherein the regenerating-temperature is equal to or less than about 400° C. above a reaction-temperature of the metal reactant and the precursor.

104. The method of claim 99, wherein the reducing agent comprises hydrogen.

105. The method of claim 99, wherein the reducing agent comprises about 1% to about 50% of hydrogen in a inert gas.

106. The method of claim 105, wherein the inert gas is Nitrogen or Ar.

107. The method of claim 99, wherein the reducing agent comprises a gas pressure of at least 1 Torr.

108. The method of claim 99, wherein the reducing agent is ammonium hypophosphite, hydrazine or borohydride.

109. The method of claim 108, wherein the reducing agent is dispensed inside the reactor as an aqueous solution or pure liquid agent.

110. A method for using the RRS of claim 38 to restore the metal reactant contaminated with an organic residue in the reactive-reactor, the method comprising:
(a) oxidatively-decomposing the organic residue to give an oxidized metal reactant; and
(b) reducing the oxidized-metal reactant with a reductive gas.

111. The method of the claim 110, further comprising purging the reactor with an inert gas before the reducing step is introduced.

112. The method of claim 110, wherein oxidatively-decomposing the organic residue comprising:
(a) heating the heater body to a decomposition temperature with the thermal source, to form a heated-heater body;
(b) introducing a heated oxidant gas into the reactive-reactor through the RRS gas inlet;
(c) contacting the heated oxidant gas with the organic residue and the reacted-metal reactant forming an oxidized gas and the oxidized-metal reactant; and
(d) discharging the oxidized gas from the reactor.

113. The method of claim 112, wherein the decomposition temperature is at least 400° C.

114. The method of claim 112, wherein the heated oxidant gas comprises is an oxygen, a sulfur, or an amino containing compound.

115. The method of claim 112, wherein the heated oxidant gas has a gas pressure of at least 1 Torr.

116. The method of claim 110, wherein reducing the oxidized-metal reactant comprising:
(a) heating the heater body to a re-generating-temperature with the thermal source, to form a heated-heater body;
(b) introducing a reducing agent into the reactive-reactor through the RRS gas inlet;
(c) contacting the reducing agent with the oxidized-metal reactant, forming an oxidized-gas and restoring the metal reactant; and
(d) purging the reaction-reactor with an inert gas.

117. The method of claim 116, wherein the metal reactant comprises a transition metal.

118. The method of claim 117, wherein the transition metal is Ni.

119. The method of claim 116, wherein the oxidized-metal reactant comprises a metal oxide.

120. The method of claim 116, wherein the regenerating-temperature is equal to or less than about 400° C. above a reaction-temperature of the metal reactant and the precursor.

121. The method of claim 116, wherein the reducing agent comprises hydrogen.

122. The method of claim 116, wherein the reducing agent comprises about 1 to about 50% of hydrogen in an inert gas.

123. The method of claim 116, wherein the inert gas is nitrogen or Ar.

124. The method of claim 116, wherein the reducing agent comprises a gas pressure of at least 1 Torr.

125. The method of claim 116, wherein the reducing agent is ammonium hypophosphite, hydrazine or borohydride.

126. The method of claim 125, wherein the reducing agent is dispensed inside the reactor as an aqueous solution or pure liquid agent.
